(19) United States
(12) Patent Application Publication
(10) Pub. No.: US 2009/0218615 A1
(43) Pub. Date: Sep. 3, 2009

(54) SEMICONDUCTOR DEVICE AND METHOD OF MANUFACTURING THE SAME

(76) Inventors: Wakako TAKEUCHI, Yokohama-Shi (JP); Hiroshi Akahori, Yokohama-Shi (JP); Masaki Kondo, Kawasaki-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/396,820

(22) Filed: Mar. 3, 2009

(30) Foreign Application Priority Data
Mar. 3, 2008 (JP) 2008-52167

(51) Int. Cl. H01L 29/792; H01L 21/28

(52) U.S. Cl. 257/326; 438/591; 257/E29.309; 257/E21.18

(57) ABSTRACT

A semiconductor device according to an embodiment of the present invention has a bit line and a word line. The device includes a substrate, a first gate insulation film formed on the substrate, a charge storage layer formed on the first gate insulation film, a second gate insulation film formed on the charge storage layer, and a gate electrode formed on the second gate insulation film, the width between side surfaces of the second gate insulation film in the bit line direction being smaller than the width between side surfaces of the gate electrode in the bit line direction.

### CROSS REFERENCE TO RELATED APPLICATION

This application is based upon and claims the benefit of priority from the prior Japanese Patent Application No. 2008-52167, filed on Mar. 3, 2008, the entire contents of which are incorporated herein by reference.

### BACKGROUND OF THE INVENTION

1. Field of the Invention

The present invention relates to a semiconductor device and a method of manufacturing the same.

2. Background Art

A kind of known nonvolatile memory is a charge trap nonvolatile memory, which is configured to store data by trapping charge in an insulator. An example of the charge trap nonvolatile memory includes a MONOS (Metal-Oxide-Nitride-Oxide-Semiconductor) flash memory (see, for example, JP-A 2007-251132 (KOKAI)). Hereinafter, it is referred to as “MONOS memory”.

In general, a cell transistor in the MONOS memory includes a substrate (such as a silicon substrate), a first gate insulation film (called a tunnel insulating film), a charge storage layer (such as a silicon nitride layer), a second gate insulation film (called a charge block layer), and a gate electrode (called a control gate). The MONOS memory controls the threshold voltage of the cell transistor by injecting charge contained in the substrate into the charge storage layer through the tunnel insulating film and trapping the charge in charge capture positions, thereby storing data.

In writing, the MONOS memory applies a write voltage to the control gate and grounds the substrate. Thereby, electrons are injected from the substrate into the charge storage layer through the tunnel insulating film by Fowler-Nordheim tunneling (FN tunneling) to be captured in the charge storage layer. As a result, the threshold voltage of the cell transistor is set to a high level. The threshold voltage can be controlled by adjusting the amount of injection of electrons by changing the control gate voltage and write time.

In erasing, the MONOS memory grounds the control gate and applies an erasing voltage to the substrate. Thereby, holes are injected from the substrate into the charge storage layer through the tunnel insulating film by FN tunneling to be combined with the electrons captured in the charge storage layer, or the electrons captured in the charge storage layer are drawn back to the substrate. As a result, the threshold voltage of the cell transistor is returned to a lower level.

With regard to the MONOS memory, there is a problem that damage to edge portions of the tunnel insulating film is caused by electric field in writing. There is a risk of such damage causing deteriorations of an endurance characteristic and a charge holding characteristic.

### SUMMARY OF THE INVENTION

An aspect of the present invention is, for example, a semiconductor device having a bit line and a word line, the device including a substrate, a first gate insulation film formed on the substrate, a charge storage layer formed on the first gate insulation film, a second gate insulation film formed on the charge storage layer, and a gate electrode formed on the second gate insulation film, the width between side surfaces of the second gate insulation film in the bit line direction being smaller than the width between side surfaces of the gate electrode in the bit line direction.

Another aspect of the present invention is, for example, a semiconductor device having a bit line and a word line, the device including a substrate, a first gate insulation film formed on the substrate, a charge storage layer formed on the first gate insulation film, a second gate insulation film formed on the charge storage layer, and a gate electrode formed on the second gate insulation film, the width between side surfaces of the second gate insulation film in the bit line direction on the upper surface of the second gate insulation film being smaller than the width between side surfaces of the gate electrode in the bit line direction on the lower surface of the gate electrode.

Another aspect of the present invention is, for example, a method of manufacturing a semiconductor device having a bit line and a word line, the method including forming a first gate insulation film, a charge storage layer, a second gate insulation film, and a gate electrode layer on a substrate in order, etching the gate electrode layer, the second gate insulation film, and the charge storage layer to form a gate electrode from the gate electrode layer, and recessing side surfaces of the second gate insulation film in the bit line direction to make the width between the side surfaces of the second gate insulation film in the bit line direction be smaller than the width between side surfaces of the gate electrode in the bit line direction.

### BRIEF DESCRIPTION OF THE DRAWINGS

FIG. 1 shows side sectional views of a semiconductor device according to a first embodiment of the present invention;

FIG. 2 shows another side sectional view of the semiconductor device according to the first embodiment;

FIGS. 3A and 3B are graphs showing relations between the amount of recession “X” of a side surface “S2” and the intensity of electric field on a first gate insulation film;

FIGS. 4 to 13 are manufacturing process diagrams for the semiconductor device according to the first embodiment;

FIG. 14 is a graph showing etching rates of an Al₂O₃ deposition layer;

FIG. 15 shows side sectional views of a semiconductor device according to a second embodiment of the present invention;

FIGS. 16A and 16B show side sectional views of semiconductor devices according to a third embodiment of the present invention; and

FIGS. 17A and 17B show side sectional views of semiconductor devices according to the third embodiment.

### DESCRIPTION OF THE EMBODIMENTS

Embodiments of the present invention will be described with reference to the drawings.

### First Embodiment

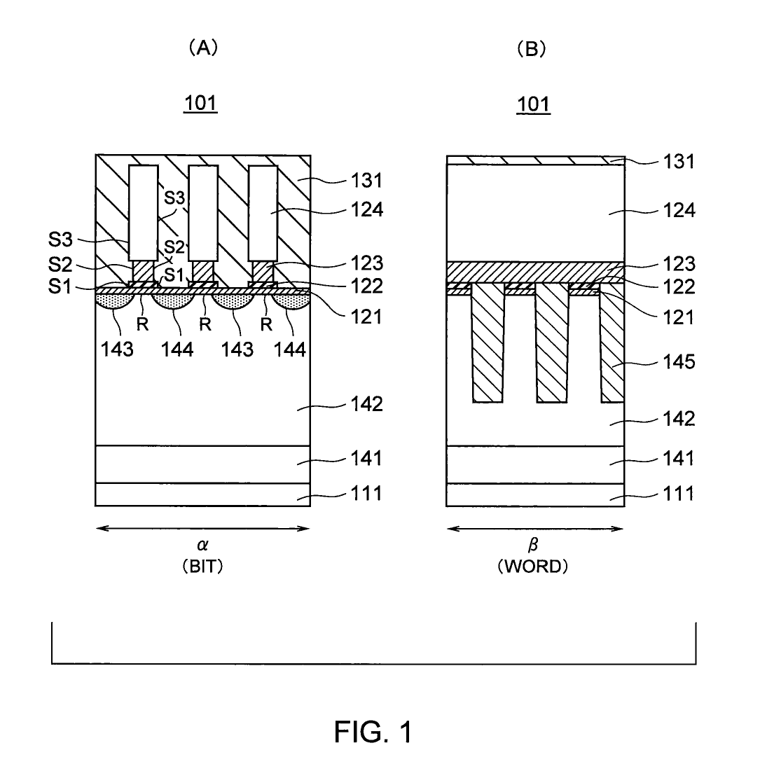

FIGS. 1(A) and 1(B) show side sectional views of a semiconductor device 101 according to a first embodiment. The semiconductor device 101 is a charge trap nonvolatile memory, more specifically, a MONOS flash memory. FIGS. 1(A) and 1(B) show side sections of cell transistors included in the semiconductor device 101.

The semiconductor device 101 has plural bit lines and word lines. An arrow “α” in FIG. 1(A) indicates a direction parallel to the bit lines (bit line direction). An arrow “β” in FIG. 1(B) indicates a direction parallel to the word lines (word line direction). Therefore, FIG. 1(A) is a section perpendicular to the word lines, and FIG. 1(B) is a section perpendicular to the bit lines.

The semiconductor device 101 includes a substrate 111, a first gate insulation film 121, a charge storage layer 122, a second gate insulation film 123, a gate electrode 124, and an inter layer dielectric 131.

The substrate 111 in this embodiment is a semiconductor substrate, more specifically, a silicon substrate. The substrate 111 may be a SOI (Semiconductor On Insulator) substrate. The substrate 111 is provided with an N-well 141, a P-well 142, a source diffusion layer 143, a drain diffusion layer 144, and an isolation layer 145. The source diffusion layer 143 is connected to a source line, and the drain diffusion layer 144 is connected to a bit line. A channel region R exists between the source diffusion layer 143 and the drain diffusion layer 144. The first gate insulation film 121, the charge storage layer 122, the second gate insulation film 123, and the gate electrode 124 are formed on the channel region R in order. The isolation layer 145 in this embodiment is an STI (Shallow Trench Isolation) layer.

The first gate insulation film 121 is formed on the substrate 111. The first gate insulation film 121 is generally called a tunnel insulating film. In this embodiment, the first gate insulation film 121 is a silicon oxide layer, and the thickness of the first gate insulation film 121 is 5 nm.

The charge storage layer 122 is formed on the first gate insulation film 121. The semiconductor device 101 stores data by trapping charge in the charge storage layer 122. In this embodiment, the charge storage layer 122 is a silicon nitride layer, and the thickness of the charge storage layer 122 is 5 nm. In FIG. 1(A), side surfaces of the charge storage layer 122 perpendicular to the bit lines are indicated by “S1”. The surfaces “S1” are side surfaces of the charge storage layer 122 in the bit line direction.

The second gate insulation film 123 is formed on the charge storage layer 122. The second gate insulation film 123 is generally called a charge block layer. In this embodiment, the second gate insulation film 123 is a high-k insulator, more specifically, an Al₂O₃ layer. The second gate insulation film 123 may alternatively be an HfAlOₓ layer or an HfO₂ layer. The Al₂O₃ layer, the HfAlOₓ layer, and the HfO₂ layer are examples of a layer containing at least aluminum or hafnium. The thickness of the second gate insulation film 123 is 15 nm in this embodiment. In FIG. 1(A), side surfaces of the second gate insulation film 123 perpendicular to the bit lines are indicated by “S2”. The surfaces “S2” are side surfaces of the second gate insulation film 123 in the bit line direction. As shown in FIG. 1(B), the second gate insulation film 123 is an insulating layer in strip form extending in the word line direction.

The gate electrode 124 is formed on the second gate insulation film 123. The gate electrode 124 is generally called a control gate. In this embodiment, the gate electrode 124 is an NiSi layer formed from a polysilicon layer. The gate electrode 124 may alternatively be a multilayer layer including a TaN layer, a WN layer, and a W layer. The thickness of the gate electrode 124 is 70 nm in this embodiment. In FIG. 1(A), side surfaces of the gate electrode 124 perpendicular to the bit lines are indicated by “S3”. The surfaces “S3” are side surfaces of the gate electrode 124 in the bit line direction. As shown in FIG. 1(B), the gate electrode 124 is a conductive layer in strip form extending in the word line direction. The gate electrode 124 is connected to the word line.

The inter layer dielectric 131 is formed on the gate electrode 124. The inter layer dielectric 131 covers the side surfaces of the charge storage layer 122, the second gate insulation film 123, and the gate electrode 124 (S1, S2, and S3). In this embodiment, the inter layer dielectric 131 is a silicon oxide layer. The inter layer dielectric 131 is an example of an insulating film of the present invention.

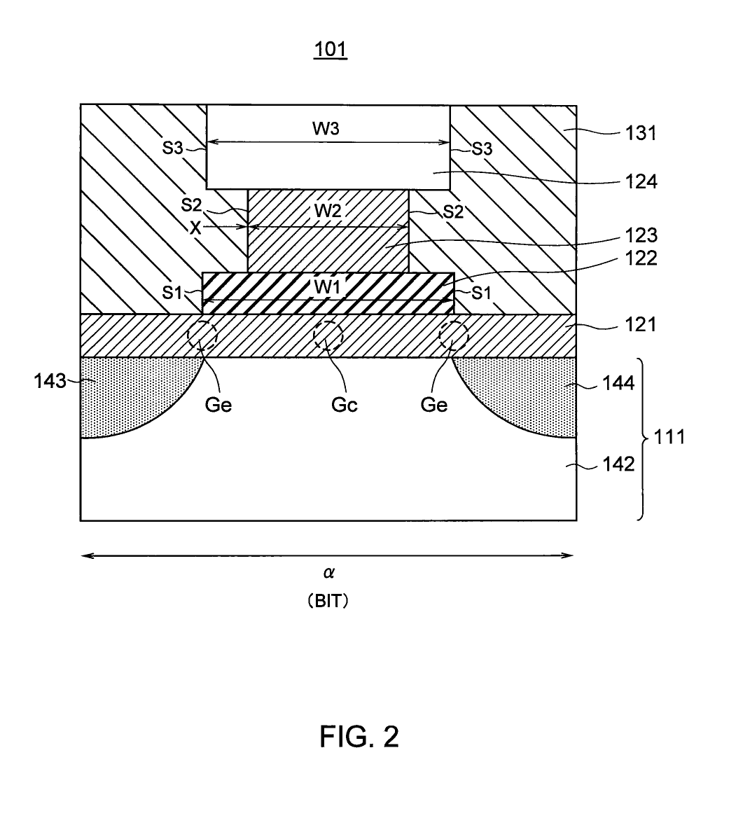

FIG. 2 shows another side sectional view of the semiconductor device 101 according to the first embodiment. FIG. 2 is an enlarged view of FIG. 1(A).

In FIG. 2, the width between the side surfaces “S2” of the second gate insulation film 123 is indicated by “W2”, and the width between the side surfaces “S3” of the gate electrode 124 is indicated by “W3”. In this embodiment, the width “W2” between the side surfaces “S2” of the second gate insulation film 123 is smaller than the width “W3” between the side surfaces “S3” of the gate electrode 124 (i.e., W2<W3). Therefore, the electric field applied to edge portions of the first gate insulation film 121 in writing is reduced in comparison with the case where W2=W3. As a result, damage to the edge portions of the first gate insulation film 121 is limited, and deteriorations of an endurance characteristic and a charge holding characteristic are limited. In FIG. 2, edge portions of the first gate insulation film 121 (gate edge portions) are indicated by “Ge”, and a central portion of the first gate insulation film 121 (gate center portion) is indicated by “Gc”.

Further, in FIG. 2, the width between the side surfaces “S1” of the charge storage layer 122 is indicated by “W1”. In this embodiment, the width “W2” between the side surfaces “S2” of the second gate insulation film 123 is smaller than the width “W1” between the side surfaces “S1” of the charge storage layer 122 (i.e., W2<W1). Further, in this embodiment, the width “W1” between the side surfaces “S1” of the charge storage layer 122 is substantially equal to the width “W3” between the side surfaces “S3” of the gate electrode 124 (i.e., W1=W3).

In this embodiment, the width “W2” between the side surfaces “S2” is smaller than the width “W3” between the side surfaces “S3”, and the side surfaces “S2” are recessed relative to the side surfaces “S3”. In this embodiment, each of the side surfaces “S2” is recessed relative to one of the side surface “S3” by an amount of 5 to 25% (preferably 15 to 25%) of the width “W3” between the side surfaces “S3”, as described below. This percentage will be referred to as the amount of recession of a side surface “S2”. In FIG. 2, the amount of recession is indicated by “X”. Between the amount of recession “X” and the widths “W2” and “W3”, there exists a relation of X={(W3−W2)/W3/W2}×100[%].

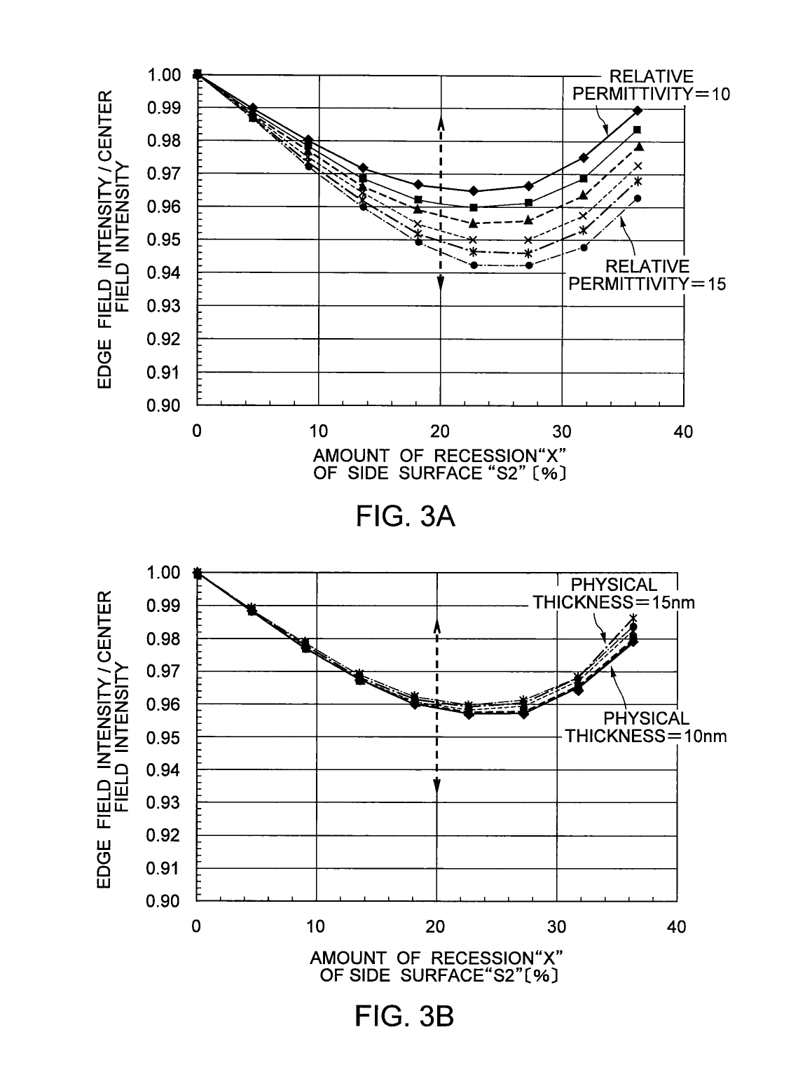

FIGS. 3A and 3B are graphs showing relations between the amount of recession “X” of a side surface “S2” and the intensity of electric field on the first gate insulation film 121. The abscissa of each graph represents the amount of recession “X”. The ordinate of each graph represents the ratio of the electric field intensity at the gate edge portion “Ge” to the electric field intensity at the gate center portion “Gc” in writing. FIG. 3A shows the results in cases where the relative permittivity of the second gate insulation film 123 is 10, 11, 12, 13, 14, and 15. FIG. 3B shows the results in cases where the thickness of the second gate insulation film 123 is 10, 11, 12, 13, 14, and 15 nm. FIGS. 3A and 3B are graphs obtained by simulation.

It can be understood from FIGS. 3A and 3B that the electric field applied to the gate edge portion “Ge” is lower when X>0% than when X=0%. Therefore, in this embodiment, “W2” is reduced relative to “W3”. In other words, the amount of recession “X” is set larger than 0%.

However, if “W2” is reduced, the second gate insulation film 123 and the inter layer dielectric 131 exist between the charge storage layer 122 and the gate electrode 124. The relative permittivity of the second gate insulation film 123 is ordinarily higher than that of the inter layer dielectric 131. Therefore, if “W2” is excessively reduced, erasure of written data is difficult to perform. Further, if “W2” is excessively reduced, a pattern collapse can occur easily. Therefore, in this embodiment, the amount of recession “X” is set to 25% or less in order that the width “W2” of the second gate insulation film 123 be not less than ½ of the width “W3” of the gate electrode 124, i.e., in order that there exist a relation of W2>W3/2.

It can also be understood that according to FIGS. 3A and 3B the electric field on the gate edge portion “Ge” is minimized at about X=15 to 30%. Therefore, for the above-described reason, it is particularly preferable to set the amount of recession “X” in the range from 15 to 25% in a case where the amount of recession “X” is set to 25% or less, and next best solution is to set the amount of recession “X” in the range from 5 to 25%.

FIG. 3A shows the results of a simulation in a case where the relative permittivity of the second gate insulation film 123 is 10 to 15. In this embodiment, the Al₂O₃ (aluminum oxide) layer, the HfAlOₓ (hafnium aluminate) layer, and the HfO₂ (hafnium oxide) layer have been mentioned as examples of the second gate insulation film 123. The relative permittivities of Al₂O₃, HfAlOₓ, and HfO₂ are 9, 16 (when Hf=29%), and 25, respectively. Thus, the values of the relative permittivity shown in FIG. 3A are practically appropriate. Consequently, a condition such as the amount of recession “X” of 15 to 25% (or 5 to 15%) can be said to be a practically appropriate condition.

It can also be understood that according to FIG. 3B the value of the electric field on the gate edge portion “Ge” is substantially independent of the thickness of the second gate insulation film 123. Thus, the above-described condition for the amount of recession “X” is appropriate regardless of the thickness of the second gate insulation film 123.

In this embodiment, the inter layer dielectric 131 is a silicon oxide layer, and the second gate insulation film 123 is a high-k insulator having a relative permittivity higher than that of the silicon oxide layer. The relative permittivity of the second gate insulation film 123 is, for example, 9 to 25. The second gate insulation film 123 may be a layer having a relative permittivity of 9 to 25 other than the Al₂O₃ layer, the HfAlOₓ layer, and the HfO₂ layer.

In this embodiment, it is assumed that the amount of recession “X” of the left side surface in FIG. 2 is equal to the amount of recession “X” of the right side surface. However, the amount of recession “X” of the left side surface in FIG. 2 may be different from the amount of recession “X” of the right side surface.

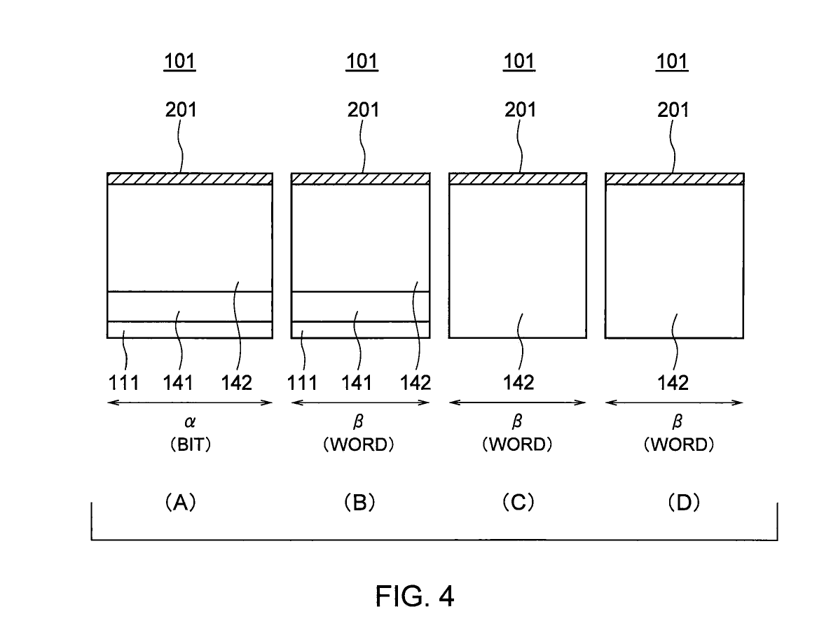

FIGS. 4 to 13 are manufacturing process diagrams for the semiconductor device 101 according to the first embodiment. In each figure, “(A)” denotes a section of the cell transistor, which is a section perpendicular to the word lines. Further, “(B)” denotes a section of the cell transistor, which is a section perpendicular to the bit lines. Further, “(C)” denotes a section of a low-voltage peripheral transistor, which is a section perpendicular to the bit lines. Further, “(D)” denotes a section of a high-voltage peripheral transistor, which is a section perpendicular to the bit lines.

First, a substrate 111, which is a P-type silicon substrate, is oxidized. Thereby, a sacrificial oxide layer 201 having a thickness of 10 nm is formed on the substrate 111 (FIG. 4). Next, an N-well 141 is formed in the substrate 111 in the cell transistor region by lithography and ion implantation (FIG. 4). In this ion implantation, phosphorous is implanted for example. This ion implantation may be performed plural times while changing the acceleration voltage and the implantation dose. Subsequently, a P-well 142 is formed in the substrate 111 in the peripheral transistor region by lithography and ion implantation (FIG. 4). In this ion implantation, boron is implanted for example. This ion implantation may be performed plural times while changing the acceleration voltage and the implantation dose. Further, lithography and ion implantation for making channel concentrations in the low-voltage transistor region and the high-voltage transistor region be different from each other may be performed.

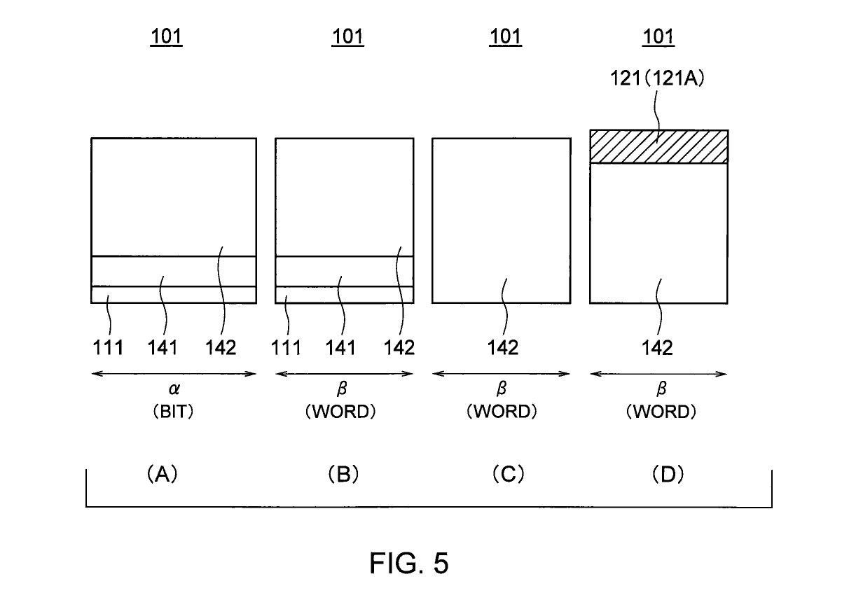

Next, the sacrificial oxide layer 201 is removed (FIG. 5). Subsequently, the substrate 111 is oxidized to form a silicon oxide layer 121A on the substrate 111. The silicon oxide layer 121A is a gate insulation film for the high-voltage peripheral transistor. Then, the silicon oxide layer 121A outside the high-voltage peripheral transistor region is removed by lithography and etching (FIG. 5).

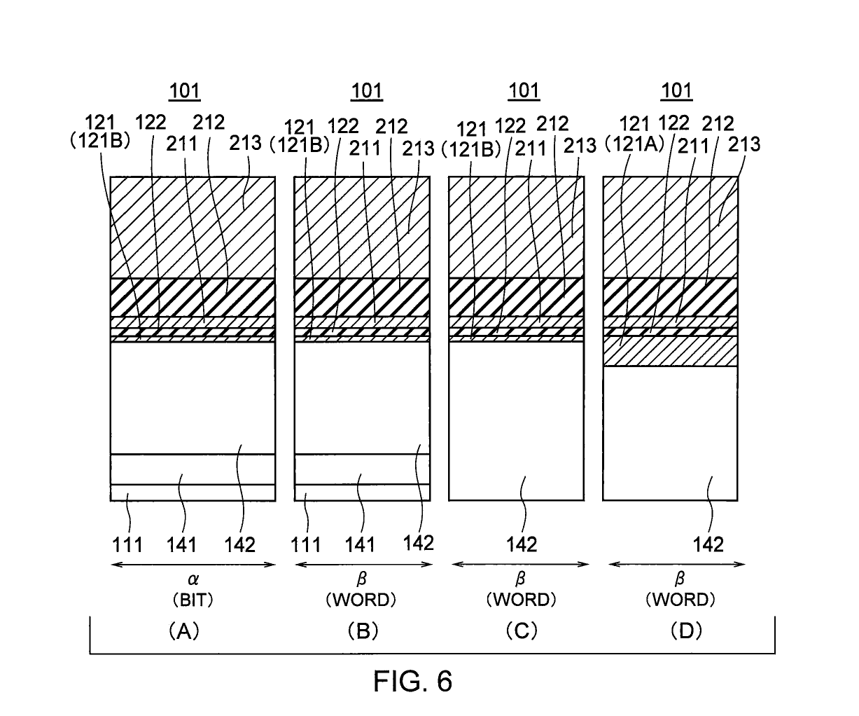

Next, the substrate 111 is oxidized to form a silicon oxide layer 121B having a thickness of 5 nm on the substrate 111 (FIG. 6). The silicon oxide layer 121B is a first gate insulation film for the cell transistor. The silicon oxide layers 121A and 121B will be referred to collectively as gate insulation film 121 (or first gate insulation film 121). Next, a silicon nitride layer 122 having a thickness of 5 nm is deposited on the gate insulation film 121 (FIG. 6). The silicon nitride layer 122 is a charge storage layer for the cell transistor. Subsequently, a silicon oxide layer 211 having a thickness of 10 nm is formed on the charge storage layer 122 (FIG. 6). Subsequently, a silicon nitride layer 212 having a thickness of 50 nm is formed on the silicon oxide layer 211 (FIG. 6). Subsequently, a mask layer 213, which is a boron doped silicate glass (BSG) layer, is formed on the silicon nitride layer 212 (FIG. 6).

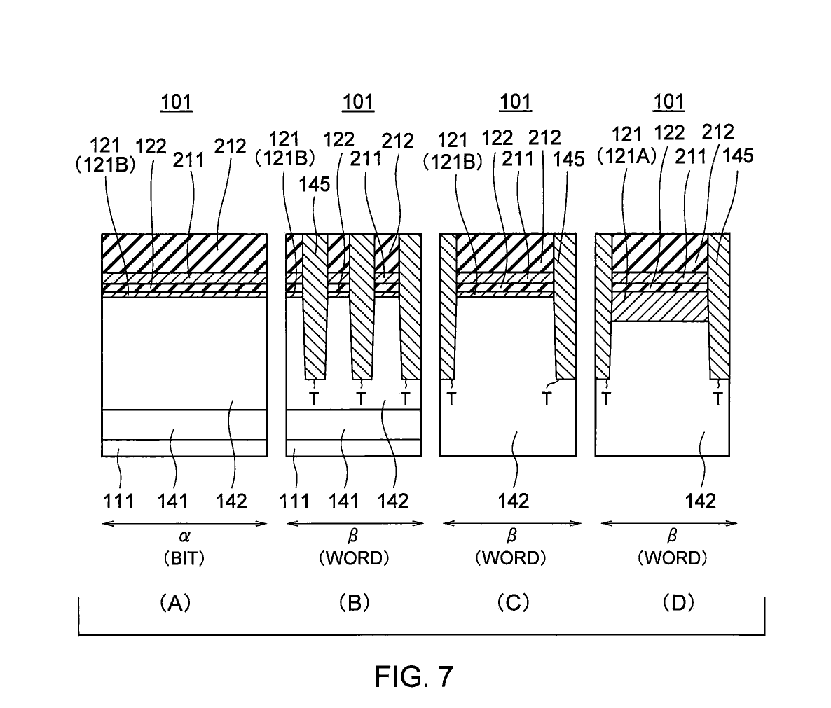

Next, the mask layer 213 is patterned by lithography and anisotropic dry etching. Subsequently, the silicon nitride layer 212, the silicon oxide layer 211, the charge storage layer 122, the gate insulation film 121, and the substrate 111 (P-well 142) is patterned by etching. Thereby, isolation trenches T extending in the bit line direction are formed on the substrate 111 (FIG. 7). Subsequently, the mask layer 213 is removed. Subsequently, the silicon oxide layer 145 is embedded in the isolation trenches T. Subsequently, the silicon oxide layer 145 is planarized by CMP (Chemical Mechanical Polishing) using the silicon nitride layer 212 as a stopper. Thereby, the isolation layer 145 extending in the bit line direction is formed on the substrate 111 (FIG. 7).

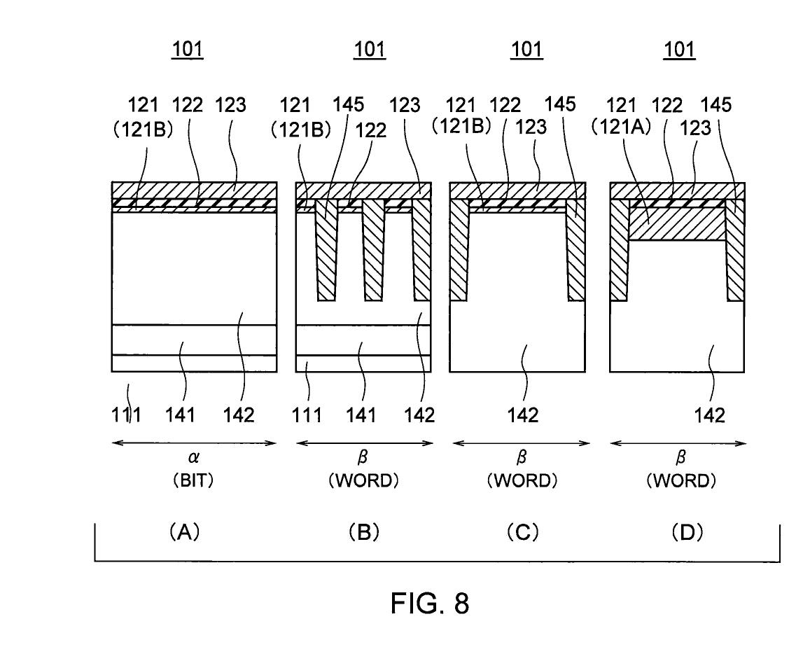

Next, the isolation layer 145 is sunk by dry etching. When this dry etching is performed, there is a need to adjust the amount of etching for the cell transistor so that the height of the upper surface of the isolation layer 145 is substantially equal to the height of the upper surface of the charge storage layer 122. On the other hand, for the peripheral transistor, there is a need to adjust the height of the upper surface of the isolation layer 145 so that no breakdown voltage failure occurs between the substrate 111 and a gate electrode 124 described below. Subsequently, the silicon nitride layer 212 is removed by wet etching. Subsequently, the silicon oxide layer 211 is removed by wet etching. Subsequently, an Al₂O₃ layer 123 having a thickness of 15 nm is deposited on the charge storage layer 122 and the isolation layer 145 (FIG. 8). The Al₂O₃ layer 123 is a second gate insulation film for the cell transistor. Subsequently, a heat treatment for partially or completely crystallizing the second gate insulation film 123 is performed.

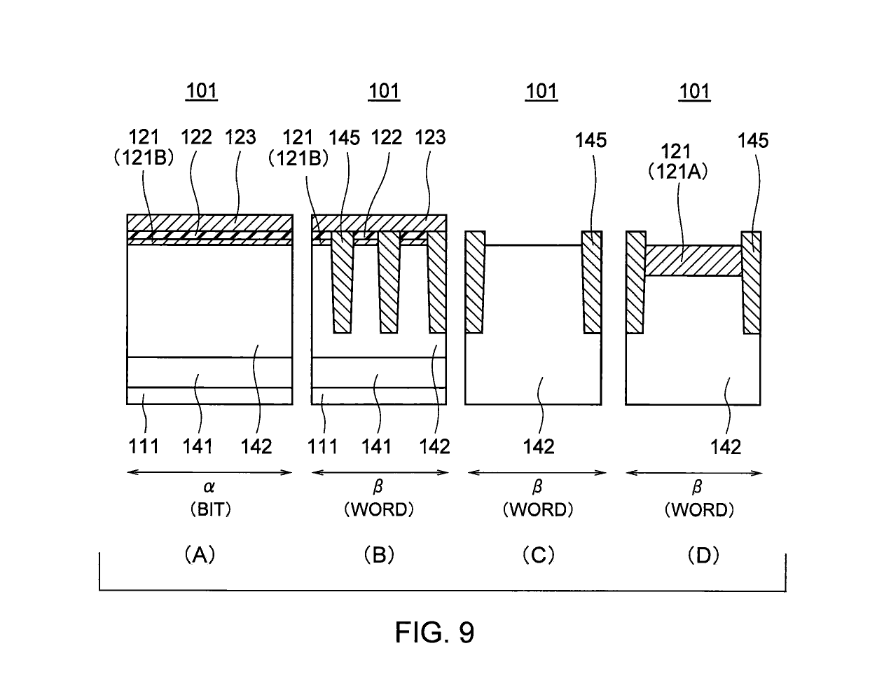

Next, a silicon nitride layer is formed on the second gate insulation film 123. Subsequently, the second gate insulation film 123 and the charge storage layer 122 outside the cell transistor region are removed by lithography and dry etching (or wet etching). Subsequently, the silicon oxide layer 121B outside the cell transistor region is removed by wet etching (FIG. 9).

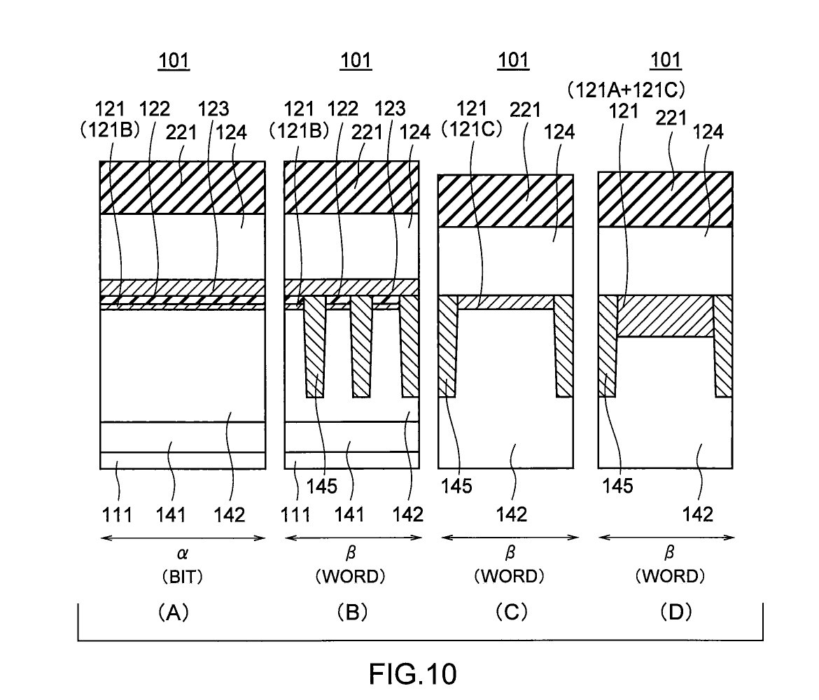

Next, a silicon oxide layer 121C having a thickness of 8 nm is deposited on the substrate 111 in the low-voltage peripheral transistor region and on the silicon oxide layer 121A in the high-voltage peripheral transistor region (FIG. 10). The silicon oxide layer 121C is a gate insulation film for the low-voltage peripheral transistor. The silicon oxide layers 121A, 121B, and 121C will be referred to collectively as gate insulation film 121 (or first gate insulation film 121). Next, a polysilicon layer 124 having a thickness of 70 nm is deposited on the second gate insulation film 123 in the cell transistor region and on the gate insulation film 121 in the peripheral transistor region (FIG. 10). The polysilicon layer 124 is a gate electrode layer for the cell transistor, the low-voltage peripheral transistor, and the high-voltage peripheral transistor. Subsequently, a mask layer 221 for gate processing is formed on the gate electrode layer 124. In this embodiment, the mask layer 221 is a silicon nitride layer.

According to the above-described processes, a multilayer structure including the first gate insulation film 121, the charge storage layer 122, the second gate insulation film 123, and the gate electrode layer 124 is formed in the cell transistor region. Further, a multilayer structure including the thin gate insulation film 121 suitable for the low-voltage peripheral transistor and the gate electrode layer 124 is formed in the low-voltage peripheral transistor region. Further, a multilayer structure including the thick gate insulation film 121 suitable for the high-voltage peripheral transistor and the gate electrode layer 124 is formed in the high-voltage peripheral transistor region. The method of forming these multilayer structures is not limited to the above-described processes.

The first gate insulation film 121 and the charge storage layer 122 in this embodiment are formed before forming the isolation layers 145. Therefore, these layers are formed not on the isolation layers 145 but between the isolation layers 145. On the other hand, the second gate insulation film 123 and the gate electrode layer 124 in this embodiment are formed after forming the isolation layers 145. Therefore, these layers are formed on the isolation layers 145 without being divided by the isolation layers 145.

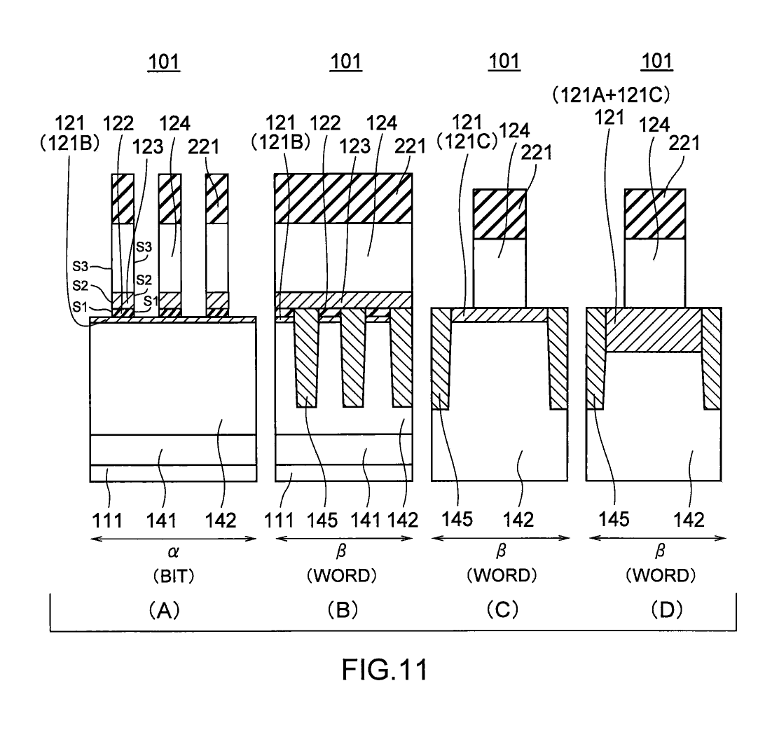

Next, gate processing is performed by lithography and dry etching. In other words, the gate electrode layer 124, the second gate insulation film 123, and the charge storage layer 122 are etched using the mask layer 221 as a mask. Thereby, the gate electrode 124 for the cell transistor, the gate electrode 124 for the low-voltage peripheral transistor, and the gate electrode 124 for the high-voltage peripheral transistor are formed from the common gate electrode layer 124 (FIG. 11). FIG. 11A shows the side surfaces “S1” of the charge storage layer 122, the side surfaces “S2” of the second gate insulation film 123, and the side surfaces “S3” of the gate electrode 124.

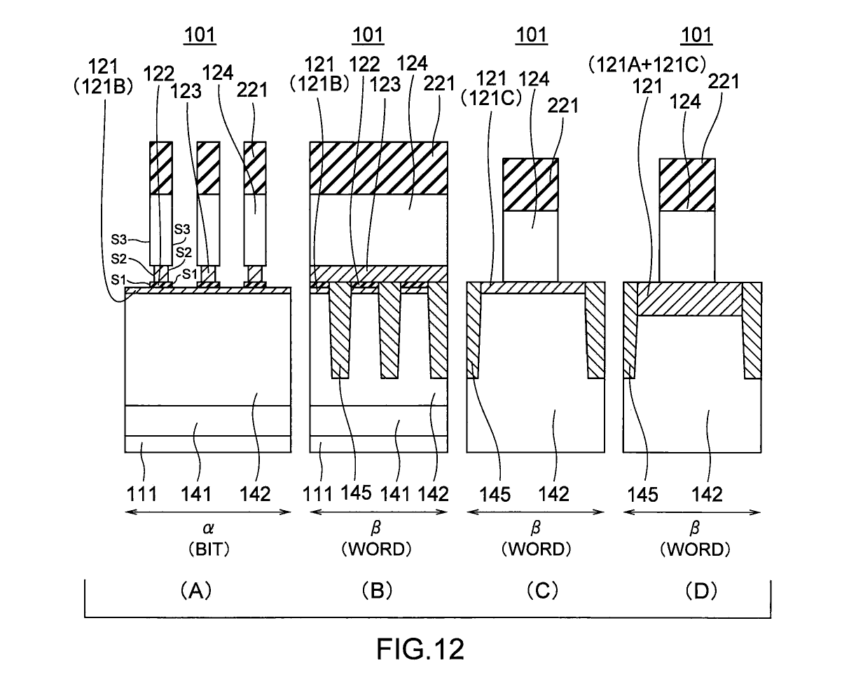

Next, a postprocess after gate processing is performed by wet etching. Thereby, the side surfaces “S2” of the second gate insulation film 123 are recessed (FIG. 12). In this wet etching, the second gate insulation film 123 having higher etching rate is etched, and the side surfaces “S2” of the second gate insulation film 123 are recessed. Thereby, the width “W2” between the side surfaces “S2” of the second gate insulation film 123 is made smaller than the width “W3” between the side surfaces “S3” of the gate electrode 124. The etching rate of the second gate insulation film 123 can be changed through the degree of crystallization in the heat treatment (FIG. 8).

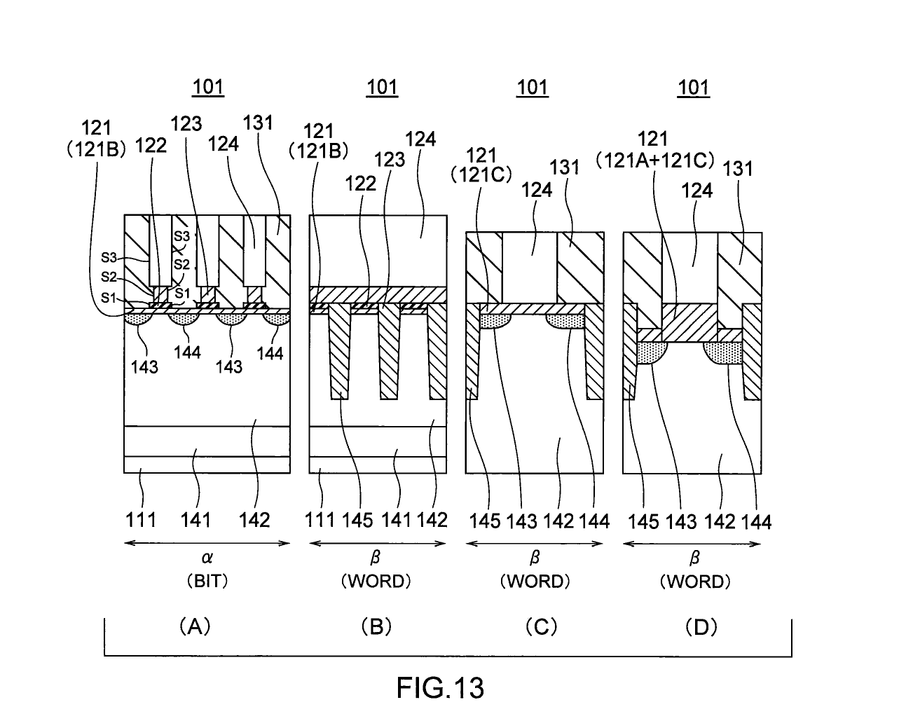

Next, a source diffusion layer 143 and a drain diffusion layer 144 are formed in the substrate 111 in the cell transistor region, the low-voltage peripheral transistor region, and the high-voltage peripheral transistor region by lithography and ion implantation (FIG. 13). The kind of ion, the implantation dose, and the acceleration voltage in this ion implantation are suitably selected for each transistor region. Annealing for activating impurities is performed, for example, at 950° C. Subsequently, an inter layer dielectric 131 is deposited on the entire surface and is planarized by CMP. Thereby, the inter layer dielectric 131 covering the side surfaces S1, S2, and S3 is formed (FIG. 13). In this embodiment, the inter layer dielectric 131 is a silicon oxide layer. Then, the mask layer 221 is removed by dry etching (FIG. 13). Subsequently, a nickel (Ni) layer is formed on the gate electrodes 124 in the cell transistor region, the low-voltage peripheral transistor region, and the high-voltage peripheral transistor region, followed by annealing at a suitable temperature. Thereby, these gate electrodes 124 are silicided to form a nickel silicide (NiSi) layer.

Then, an inter layer dielectric of a silicon oxide layer is formed on these gate electrodes 124. Further, contact plugs, via plugs, line layers, bonding pads, passivation layer, and the like are formed. In this way, the semiconductor device 101 is manufactured.

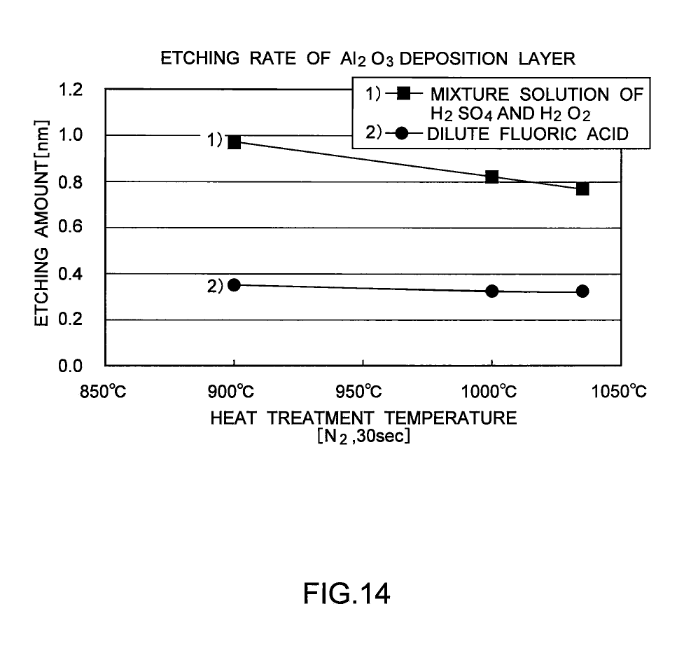

FIG. 14 is a graph showing etching rates of the Al₂O₃ deposition layer 123 in the postprocess (FIG. 12) after gate processing. In FIG. 14 shows the results of etching in a case where a mixture solution of H₂SO₄ and H₂O₂ is used as an etching solution, and etching in a case where dilute fluoric acid is used as an etching solution. The ordinate of FIG. 14 represents the amount of etching [nm] of the Al₂O₃ deposition layer 123. The abscissa of FIG. 14 represents the processing temperature [° C.] of the heat treatment (FIG. 8). As shown in the figure, the etching rate of the Al₂O₃ deposition layer 123 is dependent on the heat treatment temperature. Therefore, the etching rate of the second gate insulation film 123 can be changed through the heat treatment temperature. In this embodiment, the processing temperature of the heat treatment in FIG. 8 is set to a temperature in the range from 1000 to 1050° C., e.g., 1035° C.

In this embodiment, the postprocess is performed with an etching solution by which the second gate insulation film (Al₂O₃ layer in this embodiment) 123 can be etched in the postprocess, such as the above-mentioned two etching solutions. The etching solution used in the postprocess may be a solution other than the above-mentioned two solutions if it has an etching characteristic such as described above.

In this embodiment, as described above, the width of the side surfaces of the second gate insulation film 123 in the bit line direction is reduced relative to the width of the side surfaces of the gate electrode 124 in the bit line direction. Thereby, damage to the edge portions of the first gate insulation film 121 can be reduced, and deteriorations of the endurance characteristic and the charge holding characteristic are suppressed.

Semiconductor devices 101 according to second and third embodiments will be described. The second and third embodiments are modifications of the first embodiment. The second and third embodiments will be described mainly with respect to points of difference from the first embodiment.

### Second Embodiment

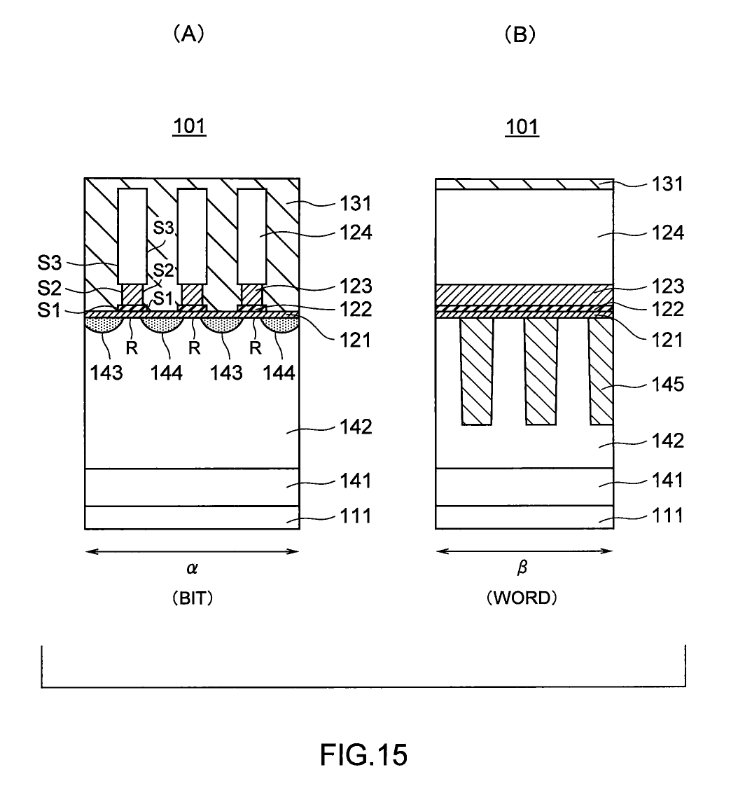

FIGS. 15(A) and 15(B) show side sectional views of a semiconductor device 101 according to a second embodiment. Referring to FIG. 1(B), the first gate insulation film 121 and the charge storage layer 122 are formed between the isolation layers 145. In contrast, referring to FIG. 15(B), the first gate insulation film 121 and the charge storage layer 122 are formed on the isolation layers 145.

The semiconductor device 101 according to the second embodiment can be manufactured by a method similar to that for the semiconductor device 101 according to the first embodiment. However, the steps of forming the silicon oxide layer 121A, the silicon oxide layer 121B, and the silicon nitride layer 122 are performed between the step shown in FIG. 7 and the step shown in FIG. 8.

The semiconductor device 101 may have a structure such as that in the first embodiment or such as that in the second embodiment.

In the second embodiment, the width of the side surfaces of the second gate insulation film 123 in the bit line direction is reduced relative to the width of the side surfaces of the gate electrode 124 in the bit line direction, as is in the first embodiment. Thereby, damage to the edge portions of the first gate insulation film 121 can be reduced, and deteriorations of the endurance characteristic and the charge holding characteristic are suppressed.

### Third Embodiment

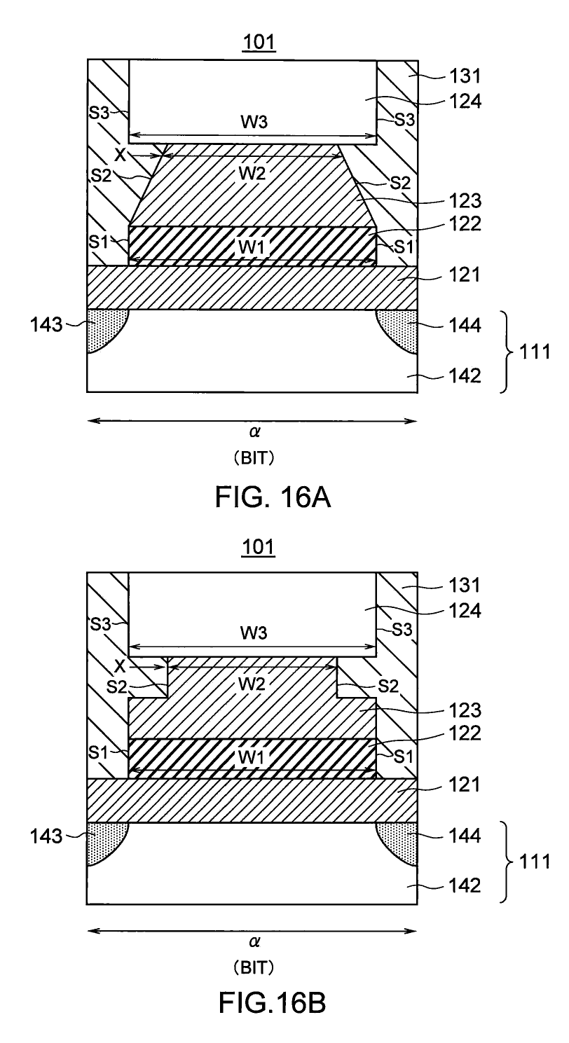

FIGS. 16A and 16B show side sectional views of semiconductor devices 101 according to a third embodiment. In each of FIGS. 16A and 16B, the width “W2” between the surface surfaces “S2” on the upper surface of the second gate insulation film 123 is smaller than the width “W3” between the side surfaces “S3” on the lower surface of the gate electrode 124. In FIG. 16A, each of the side surfaces “S2” is a flat and oblique surface having a normal inclined with respect to the horizontal direction. On the other hand, in FIG. 16B, each of the side surfaces “S2” has a stepped form. The second gate insulation film 123 and the gate electrode 124 may have structures such as those shown in FIG. 16A or FIG. 16B. In other words, it is sufficient that the relation W2<W3 is satisfied at least between the upper surface of the second gate insulation film 123 and the lower surface of the gate electrode 124. Effects described with reference to FIGS. 3A and 3B can also be produced in such structures.

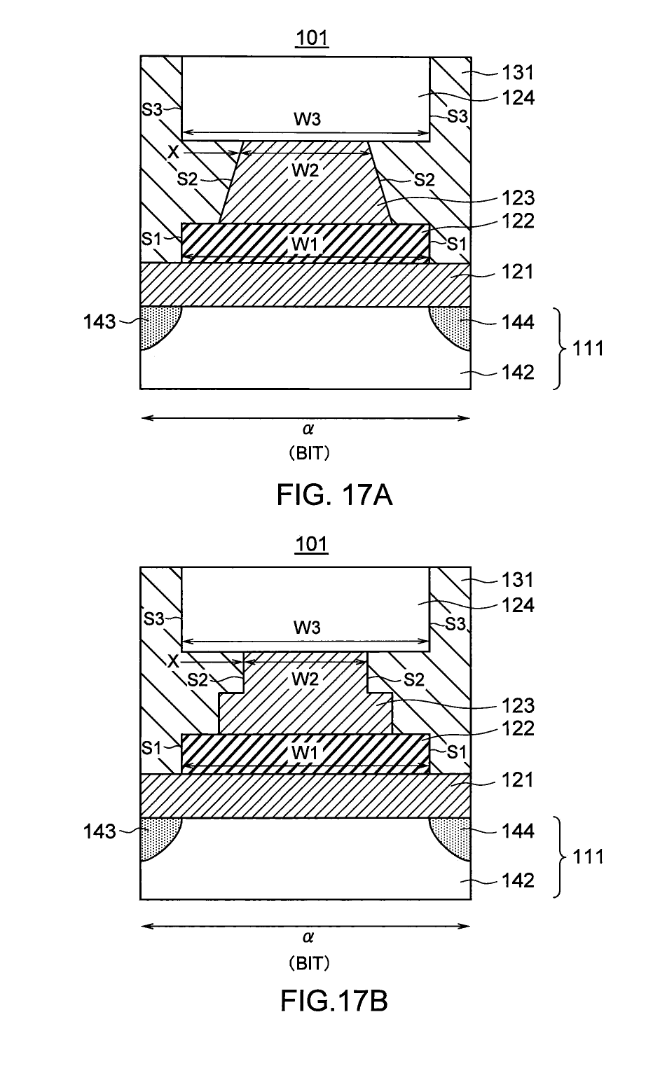

The second gate insulation film 123 and the gate electrode 124 may have structures such as those shown in FIG. 17A or FIG. 17B. In FIG. 17A, each of the side surfaces “S2” is a flat and oblique surface having a normal inclined with respect to the horizontal direction. On the other hand, in FIG. 17B, each of the side surfaces “S2” has a stepped form. However, in each of FIGS. 17A and 17B, the width “W2” between the side surfaces “S2” of the second gate insulation film 123 is smaller than the width “W3” of the side surfaces “S3” of the gate electrode 124, at any position in the side surfaces “S2”.

Each of the semiconductor device 101 according to the third embodiment can be manufactured by a method similar to that for the semiconductor device 101 according to the first embodiment. However, in the step shown in FIG. 12, the side surfaces “S2” are recessed as any of the above-described shapes.

In the cases shown in FIGS. 16B and 17B, the second gate insulation film 123 includes two layers, and the etching rate of the upper layer is set higher than that of the lower layer. Thereby, in the step shown in FIG. 12, the side surfaces “S2” are recessed as any of the above-described shape. The second gate insulation film 123 may include three or more layers. Thereby, the side surfaces “S2” having a larger number of stepped portions in comparison with those shown in FIG. 16B or 17B are formed.

In FIGS. 16A and 16B, the width between the side surfaces of the second gate insulation film 123 in the bit line direction on the upper surface of the second gate insulation film 123 is reduced relative to the width between the side surfaces of the gate electrode 124 in the bit line direction on the lower surface of the gate electrode 124. Thereby, damage to the edge portions of the first gate insulation film 121 can be reduced, and deteriorations of the endurance characteristic and the charge holding characteristic are suppressed.

Further, in FIGS. 17A and 17B, the width between the side surfaces of the second gate insulation film 123 in the bit line direction is reduced relative to the width between the side surfaces of the gate electrode 124 in the bit line direction, at any position in the side surfaces of the second gate insulation film 123 in the bit line direction. Thereby, damage to the edge portions of the first gate insulation film 121 can be reduced, and deteriorations of the endurance characteristic and the charge holding characteristic are suppressed.

The present invention is not limited to the above-described embodiments, and can be implemented by being modified within a scope not departing from its object. The materials and thicknesses of the first gate insulation film 121, the charge storage layer 122, the second gate insulation film 123, and the gate electrode 124 can be selected within a scope in which their effects are ensured. Further, the structures of the cell transistor and the peripheral transistors are not limited to the above-described ones.

As described above, the embodiments of the present invention can provide a semiconductor device and a method of manufacturing the same by which damage to the edge portions of the first gate insulation film can be limited.

1. A semiconductor device having a bit line and a word line, the device comprising:
a substrate;
a first gate insulation film formed on the substrate;
a charge storage layer formed on the first gate insulation film;
a second gate insulation film formed on the charge storage layer; and
a gate electrode formed on the second gate insulation film, the width between side surfaces of the second gate insulation film in the bit line direction being smaller than the width between side surfaces of the gate electrode in the bit line direction.

2. The device according to claim 1, wherein
the width between the side surfaces of the second gate insulation film in the bit line direction is smaller than the width between side surfaces of the charge storage layer in the bit line direction.

3. The device according to claim 1, wherein
the width between side surfaces of the charge storage layer in the bit line direction is substantially equal to the width between the side surfaces of the gate electrode in the bit line direction.

4. The device according to claim 1, wherein
each of the side surfaces of the second gate insulation film in the bit line direction is recessed relative to one of the side surfaces of the gate electrode in the bit line direction, by an amount of 5 to 25% of the width between the side surfaces of the gate electrode in the bit line direction.

5. The device according to claim 4, wherein
each of the side surfaces of the second gate insulation film in the bit line direction is recessed relative to one of the side surfaces of the gate electrode in the bit line direction, by an amount of 15 to 25% of the width between the side surfaces of the gate electrode in the bit line direction.

6. The device according to claim 1, wherein the second gate insulation film is a high-k layer.

7. The device according to claim 6, wherein the second gate insulation film contains at least aluminum or hafnium.

8. The device according to claim 1, wherein the relative permittivity of the second gate insulation film is 9 to 25.

9. The device according to claim 1, further comprising:
an insulating film covering the side surfaces of the charge storage layer, the second gate insulation film, and the gate electrode in the bit line direction,
wherein the relative permittivity of the second gate insulation film is higher than the relative permittivity of the insulating film.

10. A semiconductor device having a bit line and a word line, the device comprising:
a substrate;
a first gate insulation film formed on the substrate;
a charge storage layer formed on the first gate insulation film;
a second gate insulation film formed on the charge storage layer; and
a gate electrode formed on the second gate insulation film, the width between side surfaces of the second gate insulation film in the bit line direction on the upper surface of the second gate insulation film being smaller than the width between side surfaces of the gate electrode in the bit line direction on the lower surface of the gate electrode.

11. The device according to claim 10, wherein
each of the side surfaces of the second gate insulation film in the bit line direction has an oblique surface.

12. The device according to claim 10, wherein
each of the side surfaces of the second gate insulation film in the bit line direction has a stepped shape.

13. The device according to claim 12, wherein the second gate insulation film includes two or more layers.

14. A method of manufacturing a semiconductor device having a bit line and a word line, the method comprising:
forming a first gate insulation film, a charge storage layer, a second gate insulation film, and a gate electrode layer on a substrate in order;
etching the gate electrode layer, the second gate insulation film, and the charge storage layer to form a gate electrode from the gate electrode layer; and
recessing side surfaces of the second gate insulation film in the bit line direction to make the width between the side surfaces of the second gate insulation film in the bit line direction be smaller than the width between side surfaces of the gate electrode in the bit line direction.

15. The method according to claim 14, further comprising performing a heat treatment for the second gate insulation film,
wherein the side surfaces of the second gate insulation film in the bit direction are recessed after performing the heat treatment.

16. The method according to claim 14, wherein
the side surfaces of the second gate insulation film in the bit line direction are recessed by using an etching solution by which the second gate insulation film is etched.

17. The method according to claim 14, wherein
the side surfaces of the second gate insulation film in the bit line direction are recessed to make the width between the side surfaces of the second gate insulation film in a bit line direction be smaller than the width between the side surfaces of the gate electrode in the bit line direction, and be smaller than the width between side surfaces of the charge storage layer in the bit line direction.

18. The method according to claim 14, wherein
each of the side surfaces of the second gate insulation film is recessed relative to one of the side surfaces of the gate electrode in the bit line direction, by an amount of 5 to 25% of the width between the side surfaces of the gate electrode in the bit line direction.

19. The method according to claim 18, wherein
each of the side surfaces of the second gate insulation film is recessed relative to one of the side surfaces of the gate electrode in the bit line direction, by an amount of 15 to 25% of the width between the side surfaces of the gate electrode in the bit line direction.

20. The method according to claim 14, further comprising:
forming an insulating film whose relative permittivity is smaller than the relative permittivity of the second gate insulation film, and covering the side surfaces of the charge storage layer, the second gate insulation film, and the gate electrode in the bit line direction.
